(19) United States
(12) Patent Application Publication
(10) Pub. No.: US 2024/0186317 A1
(43) Pub. Date: Jun. 6, 2024

(54) NANOSHEET METAL-INSULATOR-METAL CAPACITOR

(71) Applicant: INTERNATIONAL BUSINESS MACHINES CORPORATION, ARMONK, NY (US)

(72) Inventors: Ruilong Xie, Niskayuna, NY (US); Julien Frougier, Albany, NY (US); Alexander Reznicek, Troy, NY (US); Sagarika Mukesh, Albany, NY (US)

(21) Appl. No.: 18/061,701

(22) Filed: Dec. 5, 2022

(51) Int. Cl. H01L 27/06; H01L 29/06; H01L 29/423; H01L 29/66; H01L 29/775

(52) U.S. Cl. CPC H01L 27/0629; H01L 28/60; H01L 29/0673; H01L 29/42392; H01L 29/66439; H01L 29/66545; H01L 29/66553; H01L 29/775

(57) ABSTRACT

A semiconductor device is provided. The semiconductor device includes: a first nanosheet device including a plurality of active semiconductor layers, a first metal stack wrapping around the active semiconductor layers, and a first gate insulator layer between the active semiconductor layers and the first metal stack; and a second nanosheet device including a second metal contact, the first metal stack wrapping around the second metal contact, and a second gate insulator between the second metal contact and the first metal stack.

### BACKGROUND

The present disclosure relates generally to fabrication methods and resulting structures for semiconductor devices and, in particular, to a semiconductor device including a metal-insulator-metal capacitor (MIMCAP) device.

Semiconductor device manufacturing and design are continually packaging more circuits into semiconductor chips as line widths and spacing between device elements shrink, while still striving for increasing semiconductor device performance. Traditionally, transistors (e.g., metal oxide semiconductor field effect transistors (MOSFETs)) are formed on the semiconductor substrate and are connected together by layers of interconnects and power structures formed above the transistors. Conventional power rails, commonly used with memory devices such as static-random access memory (SRAM), typically reside in the interconnect layers above the transistors. Conventional power rails in interconnect layers consume a significant amount of area to meet semiconductor performance requirements.

In certain examples, de-coupling capacitors, such as MIMCAPs formed in the interconnect layers, or deep trench capacitors formed in an insulating layer of a silicon-on-insulator semiconductor substrates, may be used to reduce power rail noise and increase semiconductor device performance. The high frequency and low power of semiconductor chips may require the use of decoupling capacitors for mitigating power supply or switching noise caused by changes in current flowing in an integrated chip. One popular choice at the so-called “back-end of line” (BEOL) for decoupling capacitors are MIMCAPs for high capacitor density. As the need for MIMCAPs at these levels is increasing as well as the portion of the chip design available for capacitors in the designs is shrinking, some of the existing MIMCAP designs may not be available to the chip designer. Some MIMCAP designs require additional lithography masks, additional levels of processing and relatively large areas of the chip. Stacked capacitors (>2 electrodes) with metal/insulator (high-K)/metal stacks have been proposed for MIMCAP devices in order to obtain higher capacitance density per area.

In certain semiconductor device fabrication processes, a large number of semiconductor devices, such as n-type field effect transistors (nFETs) and p-type field effect transistors (pFETs), may be fabricated on a single wafer. Non-planar transistor device architectures (e.g., fin-type FETs (FinFETs) and nanosheet FETs) can provide increased device density and increased performance over planar transistors. As semiconductor integrated circuits (ICs) and/or chips become smaller, the implementation of stacked nanosheets in semiconductor devices has increased. Nanosheets generally refer to two-dimensional nanostructures with a thickness range on the order of about 3 nanometer (nm) to about 20 nm, and they can facilitate the fabrication of non-planar semiconductor devices having a reduced footprint compared to conventional planar-type semiconductor devices. For example, nanosheet transistors, in contrast to conventional planar FETs, include a gate stack that wraps around the full perimeter of multiple stacked nanosheet channel regions for a reduced device footprint and improved control of channel current flow. Nanosheet transistor configurations may enable fuller depletion in the nanosheet channel regions and reduce short-channel effects. In addition, certain gate-all-around structures for FETs (e.g., nanosheet devices) may provide an improved electro-static control in order to meet the requirements for further device scaling. Accordingly, nanosheets and nanowires are seen as feasible options for reducing the footprints of semiconductor transistor devices to 7 nanometers or less.

Thus, it may be desirable to provide processes and designs which can be used to make improved MIMCAPs with increased capacitance density.

### SUMMARY

Embodiments of the present disclosure relate to a semiconductor structure. A semiconductor device is provided. The semiconductor device includes: a first nanosheet device including a plurality of active semiconductor layers, a first metal stack wrapping around the active semiconductor layers, and a first gate insulator layer between the active semiconductor layers and the first metal stack; and a second nanosheet device including a second metal contact, the first metal stack wrapping around the second metal contact, and a second gate insulator layer between the second metal contact and the first metal stack.

Embodiments of the present disclosure relate to a method of manufacturing a semiconductor device. The method includes: forming a nanosheet stack that includes alternating layers of sacrificial layers and active semiconductor layers; recessing the sacrificial layers; forming inner spacers in the recessed areas of the sacrificial layers; removing the sacrificial layers; forming a first gate insulator layer on the active semiconductor layers and the inner spacers; forming a first metal stack in spaces where the sacrificial layers were removed; removing the active silicon layers and exposed portions of the first gate insulating layer; removing the inner spacer; forming a second gate insulator layer on the first metal stack; and forming a second metal contact on the second gate insulator layer such that the first metal stack wraps around the second metal contact.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1A shows a schematic cross-sectional diagram for a semiconductor device including a nanosheet device at an intermediate stage of the fabrication process, taken along the metal oxide semiconductor field effect transistor (MOSFET) line of FIG. 1C, in accordance with embodiments.

FIG. 1B shows a schematic cross-sectional diagram for the semiconductor device of FIG. 1A including a nanosheet metal-insulator-metal capacitor (MIMCAP) device, taken along the line MIM of FIG. 1C, in accordance with an embodiment.

FIG. 1C shows a top-down view of the semiconductor device of FIGS. 1A and 1B.

FIG. 2A shows a schematic cross-sectional diagram for the semiconductor device including the nanosheet device of FIG. 1A at a subsequent stage of the fabrication process, taken along the MOSFET line of FIG. 1C, in accordance with embodiments.

FIG. 2B shows a schematic cross-sectional diagram for the semiconductor device of FIG. 1B including the nanosheet MIMCAP device at a subsequent stage of the fabrication process, taken along the line MIMCAP of FIG. 1C, in accordance with an embodiment.

FIG. 3A shows a schematic cross-sectional diagram for the semiconductor device including the nanosheet device of FIG. 2A at a subsequent stage of the fabrication process, taken along the MOSFET line of FIG. 1C, in accordance with embodiments.

FIG. 3B shows a schematic cross-sectional diagram for the semiconductor device of FIG. 2B including the nanosheet MIMCAP device at a subsequent stage of the fabrication process, taken along the line MIMCAP of FIG. 1C, in accordance with an embodiment.

FIG. 4A shows a schematic cross-sectional diagram for the semiconductor device including the nanosheet device of FIG. 3A at a subsequent stage of the fabrication process, taken along the MOSFET line of FIG. 1C, in accordance with embodiments.

FIG. 4B shows a schematic cross-sectional diagram for the semiconductor device of FIG. 3B including the nanosheet MIMCAP device at a subsequent stage of the fabrication process, taken along the line MIMCAP of FIG. 1C, in accordance with an embodiment.

FIG. 5A shows a schematic cross-sectional diagram for the semiconductor device including the nanosheet device of FIG. 4A at a subsequent stage of the fabrication process, taken along the MOSFET line of FIG. 1C, in accordance with embodiments.

FIG. 5B shows a schematic cross-sectional diagram for the semiconductor device of FIG. 4B including the nanosheet MIMCAP device at a subsequent stage of the fabrication process, taken along the line MIMCAP of FIG. 1C, in accordance with an embodiment.

FIG. 6A shows a schematic cross-sectional diagram for the semiconductor device including the nanosheet device of FIG. 5A at a subsequent stage of the fabrication process, taken along the MOSFET line of FIG. 1C, in accordance with embodiments.

FIG. 6B shows a schematic cross-sectional diagram for the semiconductor device of FIG. 5B including the nanosheet MIMCAP device at a subsequent stage of the fabrication process, taken along the line MIMCAP of FIG. 1C, in accordance with an embodiment.

FIG. 7A shows a schematic cross-sectional diagram for the semiconductor device including the nanosheet device of FIG. 6A at a subsequent stage of the fabrication process, taken along the MOSFET line of FIG. 1C, in accordance with embodiments.

FIG. 7B shows a schematic cross-sectional diagram for the semiconductor device of FIG. 6B including the nanosheet MIMCAP device at a subsequent stage of the fabrication process, taken along the line MIMCAP of FIG. 1C, in accordance with an embodiment.

FIG. 8A shows a schematic cross-sectional diagram for the semiconductor device including the nanosheet device of FIG. 7A at a subsequent stage of the fabrication process, taken along the MOSFET line of FIG. 1C, in accordance with embodiments.

FIG. 8B shows a schematic cross-sectional diagram for the semiconductor device of FIG. 7B including the nanosheet MIMCAP device at a subsequent stage of the fabrication process, taken along the line MIMCAP of FIG. 1C, in accordance with an embodiment.

FIG. 9A shows a schematic cross-sectional diagram for the semiconductor device including the nanosheet device of FIG. 8A at a subsequent stage of the fabrication process, taken along the MOSFET line of FIG. 9C, in accordance with embodiments.

FIG. 9B shows a schematic cross-sectional diagram for the semiconductor device of FIG. 8B including the nanosheet MIMCAP device at a subsequent stage of the fabrication process, taken along the line MIMCAP of FIG. 9C, in accordance with an embodiment.

FIG. 9C shows a top-down view of the semiconductor device of FIGS. 9A and 9B.

FIG. 10A shows a schematic cross-sectional diagram for the semiconductor device including the nanosheet device of FIG. 9A at a subsequent stage of the fabrication process, taken along the MOSFET line of FIG. 10C, in accordance with embodiments.

FIG. 10B shows a schematic cross-sectional diagram for the semiconductor device of FIG. 9B including the nanosheet MIMCAP device at a subsequent stage of the fabrication process, taken along the line MIMCAP of FIG. 10C, in accordance with an embodiment.

FIG. 10C shows a top-down view of the semiconductor device of FIGS. 10A and 10B.

FIG. 11 shows a schematic cross-sectional diagram for the semiconductor device including the nanosheet device of FIG. 10B at a subsequent stage of the fabrication process, taken along the MIMCAP line of FIG. 10C, in accordance with embodiments.

FIG. 12 shows a schematic cross-sectional diagram for the semiconductor device including the nanosheet device of FIG. 11 at a subsequent stage of the fabrication process, taken along the MIMCAP line of FIG. 10C, in accordance with embodiments.

FIG. 13 shows a schematic cross-sectional diagram for the semiconductor device including the nanosheet device of FIG. 12 at a subsequent stage of the fabrication process, taken along the MIMCAP line of FIG. 10C, in accordance with embodiments.

FIG. 14 shows a schematic cross-sectional diagram for the semiconductor device including the nanosheet device of FIG. 13 at a subsequent stage of the fabrication process, taken along the MIMCAP line of FIG. 10C, in accordance with embodiments.

FIG. 15A shows a schematic cross-sectional diagram for the semiconductor device including the nanosheet device of FIG. 14 at a subsequent stage of the fabrication process, taken along the MIMCAP line of FIG. 15B, in accordance with embodiments.

FIG. 15B shows a top-down view of the semiconductor device of FIG. 15A.

### DETAILED DESCRIPTION

The present disclosure is directed to semiconductor devices including a metal-insulator-metal capacitor (MIMCAP) and/or a transistor (e.g., a MOSFET device) formed as part of an overall nanosheet structure. Nanosheet technology has been proposed as a next generation device architecture. The present embodiments provide methods and devices to form high density MIMCAPs within the context of a nanosheet structure. In certain embodiments, the MIMCAP device may have applications as an embedded dynamic random access memory (DRAM) device, or as a decoupling capacitor, in back-end-of-line (BEOL) application, etc. However, these applications are merely examples of applications for the MIMCAPs of the present embodiments. In certain embodiments, the nanosheet MIMCAP may be formed in combination with a nanosheet MOSFET device. However, in other embodiments, it should be appreciated that the MIMCAP may be formed as part of the nanosheet structure without forming the MOSFET device.

As used herein, a “DRAM” refers to a memory device wherein a basic cell is provided with a selection transistor and a capacitor. A gate of the selection transistor is connected to a word line, a drain thereof is connected to a bit line, and a source thereof is connected to an electrode or the capacitor. A gate of the selection transistor is connected to a word line, a drain thereof is connected to a bit line, and a source thereof is connected to an electrode or the capacitor that is, to an earthed electrode.

As used herein, the term “capacitor” denotes a structure including one or more pairs of electrically conductive materials separated and insulated from each other by a multilayer dielectric for storing a charge. Certain of the present embodiments specifically applies to the multilayer dielectric in a metal-insulator-metal capacitor (MIMCAP).

As used herein, the term “electrode” denotes a component of a capacitor representing one of at least two electrically conductive materials of the capacitor that are separated by a multilayer dielectric in accordance with the present embodiments.

As used herein, the term “dielectric” denotes a non-metallic material having a room temperature conductivity of less than about 10-10(-m)-1.

As used herein, the term “high-K” denotes a material having a dielectric constant (κ) that is greater than the dielectric constant of silicon oxide (SiO₂) at room temperature (20° C.-25° C.) and atmospheric pressure (1 atm).

The flowcharts and cross-sectional diagrams in the Figures illustrate methods of manufacturing nanosheet FET devices according to various embodiments. In some alternative implementations, the manufacturing steps/operations may occur in a different order that that which is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, according to embodiments of the present disclosure a semiconductor device may include a nanosheet structure that may be configured as a field effect transistor (FET) and/or a MIMCAP. In general, gate-all-around FET devices (e.g., nanosheet devices) can provide for improved electro-static control in order to meet the requirements for further device scaling. The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the channel as a nanostructure. For example, a so-called gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions.

Semiconductor nanosheet FET devices typically include one or more suspended nanosheets that serve as the channel. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized. For n-type FETs, the channel nanosheets are typically silicon (Si) and the sacrificial nanosheets are typically silicon germanium (SiGe). For p-type FETs, the channel nanosheets can be SiGe and the sacrificial nanosheets can be Si. In some implementations, the channel nanosheet of a p-type FET can be SiGe or Si, and the sacrificial nanosheets can be Si or SiGe. Forming the GAA nanosheets from alternating layers of channel nanosheets formed from a first type of semiconductor material (e.g., Si for n-type FETs, and SiGe for p-type FETs) and sacrificial nanosheets formed from a second type of semiconductor material (e.g., SiGe for n-type FETs, and Si for p-type FETs) provides superior channel electrostatics control, which is necessary for continuously scaling gate lengths down to seven (7) nanometer CMOS technology and below.

An epitaxy process is typically performed to grow source/drain epitaxy structures from the surface of the wafer to contact the opposing ends of the nanosheets. A metal source/drain contact is then typically formed on the upper surface of the source/drain epitaxy structure to provide the final source/drain contacts of the device. The use of multiple layered SiGe/Si sacrificial/channel nanosheets (or Si/SiGe sacrificial/channel nanosheets) to form the channel regions in GAA FET semiconductor devices provides desirable device characteristics, including the introduction of strain at the interface between SiGe and Si.

The present embodiments enable the formation of a MIMCAP device within the stacked nanosheet structure, which may allow for improvements in device density.

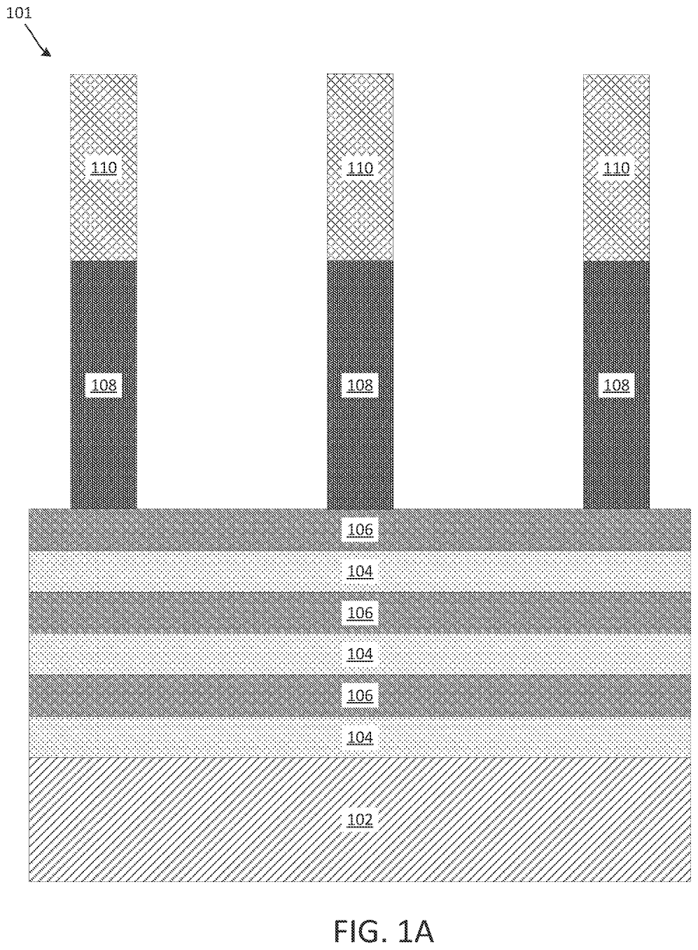

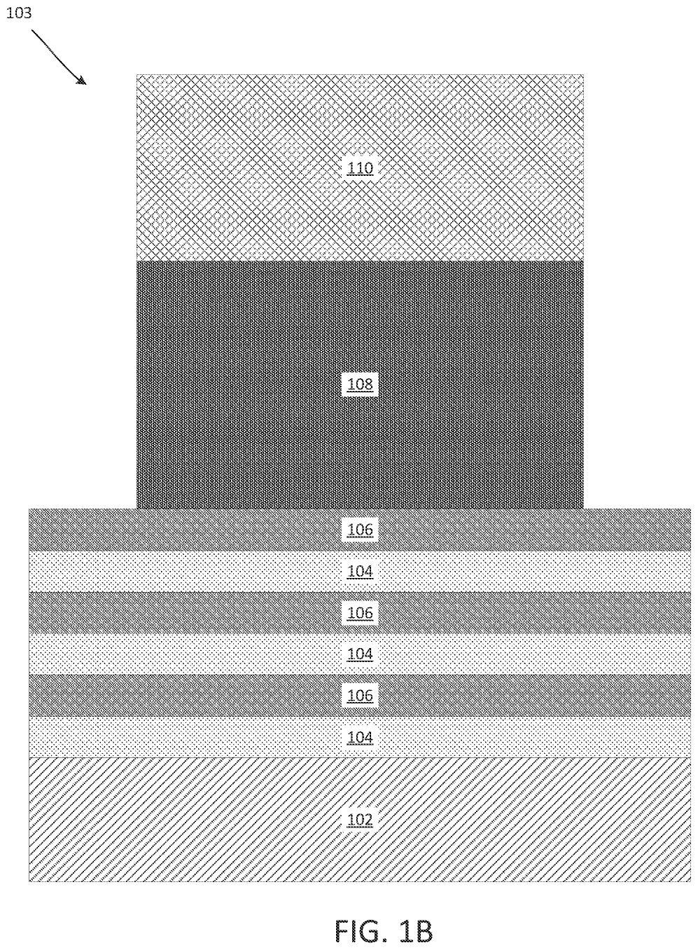

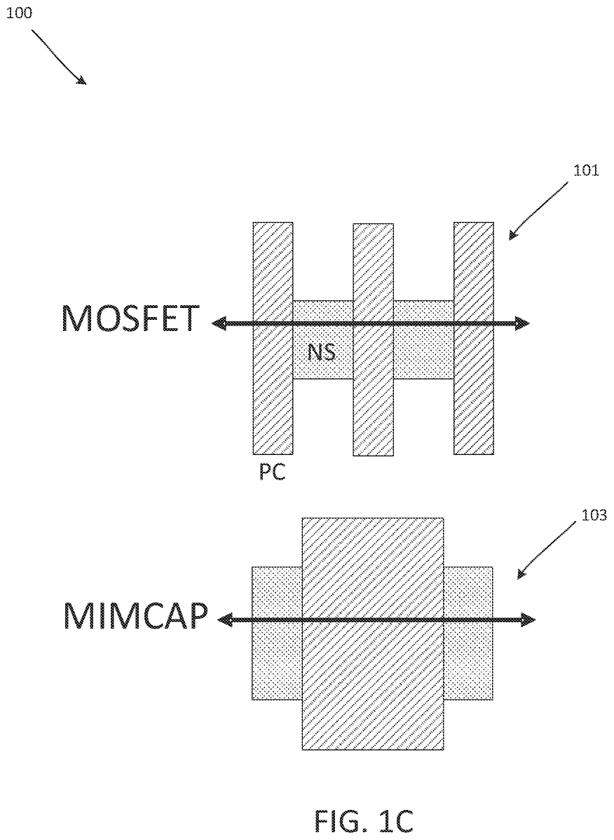

Referring now to the drawings in which like numerals represent the same or similar elements and initially to FIG. 1A, this figure shows a schematic cross-sectional diagram for a semiconductor device 100 including a nanosheet MOSFET device 101 at an intermediate stage of the fabrication process, taken along the metal oxide semiconductor field effect transistor (MOSFET) line of FIG. 1C, in accordance with embodiments. As shown in the top-down view of FIG. 1C, the semiconductor device 100 may include both a MOSFET device and a MIMCAP device 103. However, as mentioned above, in other embodiments the semiconductor device 100 may include the MIMCAP device without the MOSFET device. It should be appreciated that in certain embodiments, the MOSFET device 101 fabrication process is shown in parallel with the MIMCAP device 103 fabrication process for ease of understanding with regard to forming the MIMCAP device 103 around the same nanosheet stack structure that is used to form the MOSFET device 101.

In certain examples, several back end of line (“BEOL”) layers (not shown) and front end of line (FEOL) layers (not shown) may be formed. In general, the front end of line (FEOL) is the first portion of IC fabrication where the individual devices (transistors, capacitors, resistors, etc.) are patterned in the semiconductor. FEOL generally covers everything up to (but not including) the deposition of metal interconnect layers. In general, the BEOL is the second portion of IC fabrication where the individual devices (transistors, capacitors, resistors, etc.) are interconnected with wiring on the wafer. The BEOL metal layers (not shown) can include, for example, Cu, TaN, Ta, Ti, TiN or a combination thereof. A BEOL dielectric layer (not shown) may be formed on the sides of one or more of the BEOL metal layers. The BEOL dielectric layer may be composed of, for example, SiOₓ, SiNₓ, SiBCN, low-κ, NBLOK, or any other suitable dielectric material. The structure including the FEOL/BEOL layers (not shown) may be a starting structure upon which the SRAM devices are formed.

As shown in the semiconductor device 100 of FIG. 1A, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. The substrate 102 may be comprised of any other suitable material(s) than those listed above.

As shown in FIG. 1A, a multi-layer nanosheet stack is formed on the substrate 102. The nanosheet stack includes a sacrificial layer 104, followed by the formation of an active semiconductor layer 106. In an example, the sacrificial layer 104 is composed of silicon-germanium (e.g., SiGe35, or more generally, where the Ge ranges from about 15-35%). In an example, the active semiconductor layer 106 is composed of silicon. Several additional layers of the sacrificial layer 104 and the active semiconductor layer 106 are alternately formed in succession to complete the nanosheet stack. In the example illustrated in FIGS. 1A and 1B, there are a total of three sacrificial layers 104 and three active semiconductor layers 106 that are alternately formed to form the nanosheet stack. However, it should be appreciated that any suitable number of alternating layers may be formed.

In certain embodiments, the sacrificial layers 104 have a vertical thickness ranging, for example, from approximately 3 nm to approximately 20 nm. In certain embodiments, the active semiconductor layers 106 have a vertical thickness ranging, for example, from approximately 3 nm to approximately 10 nm. Although the range of 3-20 nm is cited as an example range of thickness, other thicknesses of these layers may be used. In certain examples, certain of the sacrificial layers 104 or the active semiconductor layers 106 may have different thicknesses relative to one another. Therefore, multiple epitaxial growth processes can be performed to form the alternating sacrificial layers 104 and the active semiconductor layers 106.

In certain embodiments, it may be desirable to have a small vertical spacing (VSP) between adjacent nanosheet layers in a stack of nanosheets to reduce the parasitic capacitance and to improve circuit speed. For example, the VSP (the distance between the bottom surface of a first nanosheet layer and the top surface of an adjacent second nanosheet layer) may range from 5 nm to 15 nm. However, the VSP must be of a sufficient value to accommodate the gate stack that will be formed in the spaces created by later removal of the sacrificial layers 104.

FIG. 1B shows a schematic cross-sectional diagram for the semiconductor device of FIG. 1A including a nanosheet metal-insulator-metal capacitor (MIMCAP) device 103 at the same intermediate stage of the fabrication process as the MOSFET device 101 shown in FIG. 1A, taken along the line MIMCAP of FIG. 1C, in accordance with an embodiment. As shown in both FIGS. 1A and 1B, a dummy gate 108 is formed on the nanosheet stack (i.e., the plurality of sacrificial layers 104 and semiconductor layers 106). The dummy gate 108 may be formed by any suitable deposition technique known to one of skill in the art. In one example, the dummy gate 108 is formed by depositing a thin SiO₂ layer, followed by depositing a layer of amorphous Si (a-Si). The dummy gates 108 may be formed, followed by depositing a dielectric hardmask 110 material, such as silicon nitride or silicon dioxide, on a layer of the dummy gate 108 material and then applying a photoresist pattern to the hardmask 110 material using a lithography process. The photoresist pattern is then transferred into the hardmask 110 material using, e.g., a dry etch process to form a patterned hardmask 110. Next, the photoresist pattern is removed, and the gate pattern is then transferred into the dummy gate 108 during an anisotropic selective etching process, such as reactive ion etching (RIE). Alternatively, the dummy gates 108 and the hardmask 110 can be formed by other patterning techniques such as spacer image transfer. FIG. 1C shows a top-down view of the semiconductor device 100 of FIGS. 1A and 1B.

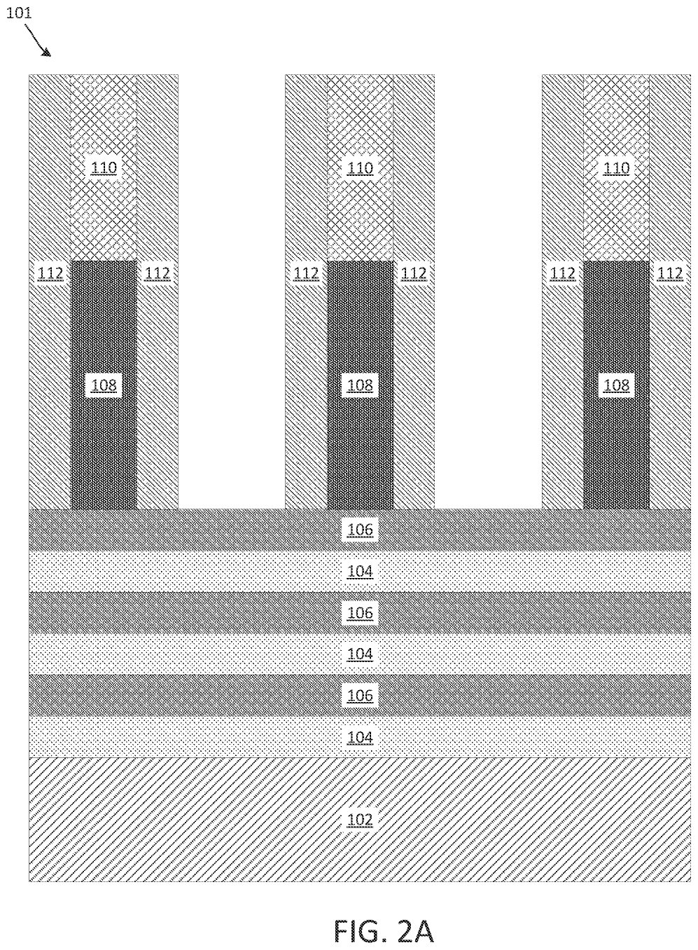

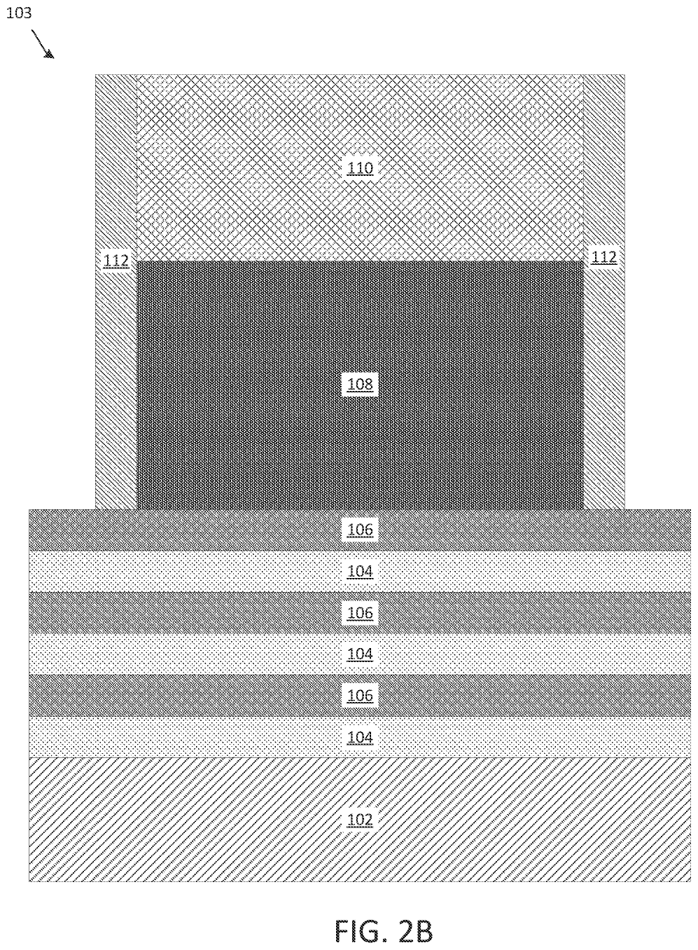

Referring now to FIG. 2A, this figure shows a schematic cross-sectional diagram for the semiconductor device 100 including the MOSFET device 101 of FIG. 1A at a subsequent stage of the fabrication process, taken along the MOSFET line of FIG. 1C, in accordance with embodiments. As shown in FIG. 2A, the dummy gates 108 are surrounded by a spacer layer 112 that is formed from, e.g., silicon nitride or silicon dioxide. Although these materials are specifically contemplated, it should be understood that any appropriate material may be used. As shown in both FIGS. 2A and 2B, the spacer layer 112 covers the sidewalls of the dummy gate 108 and the hardmask 110. The spacer layer 112 can be composed of various nitride materials including, but not limited to, silicon nitride (SiN), SiBCN, SiOCN, SiOC, etc. In certain embodiments, although not shown in the cross-sectional view of FIGS. 2A and 2B, the dummy gate 108 extends into and out of the page to wrap around the edges of the nanosheet stack, and the subsequent removal of the dummy gate 108 allows an access point for later removal of the sacrificial layers 104. FIG. 2B shows a schematic cross-sectional diagram for the semiconductor device 100 of FIG. 1B including the nanosheet MIMCAP device 103 at a subsequent stage of the fabrication process, taken along the line MIMCAP of FIG. 1C, in accordance with an embodiment.

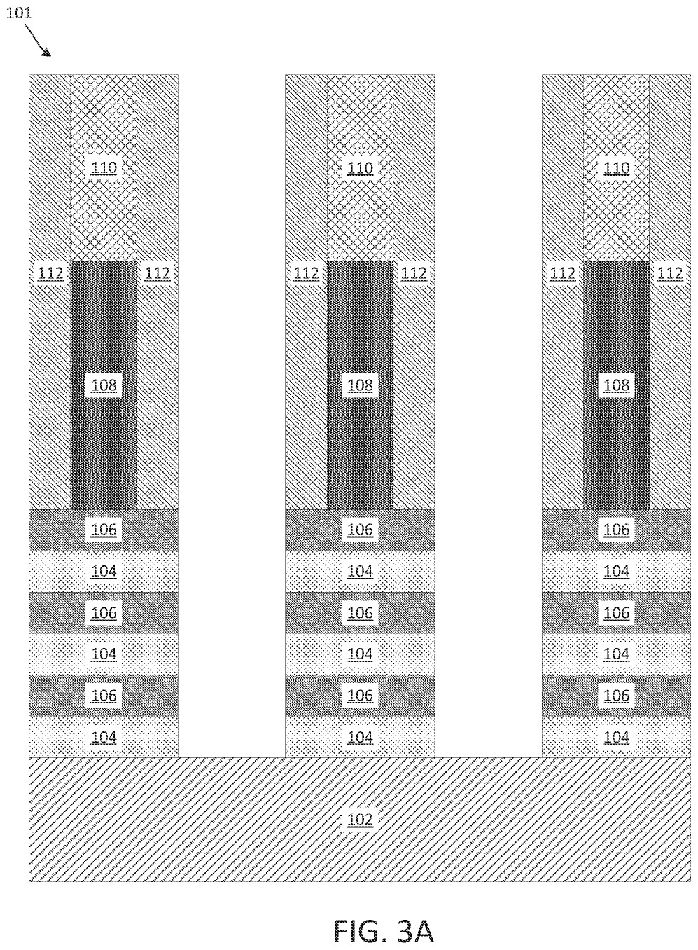

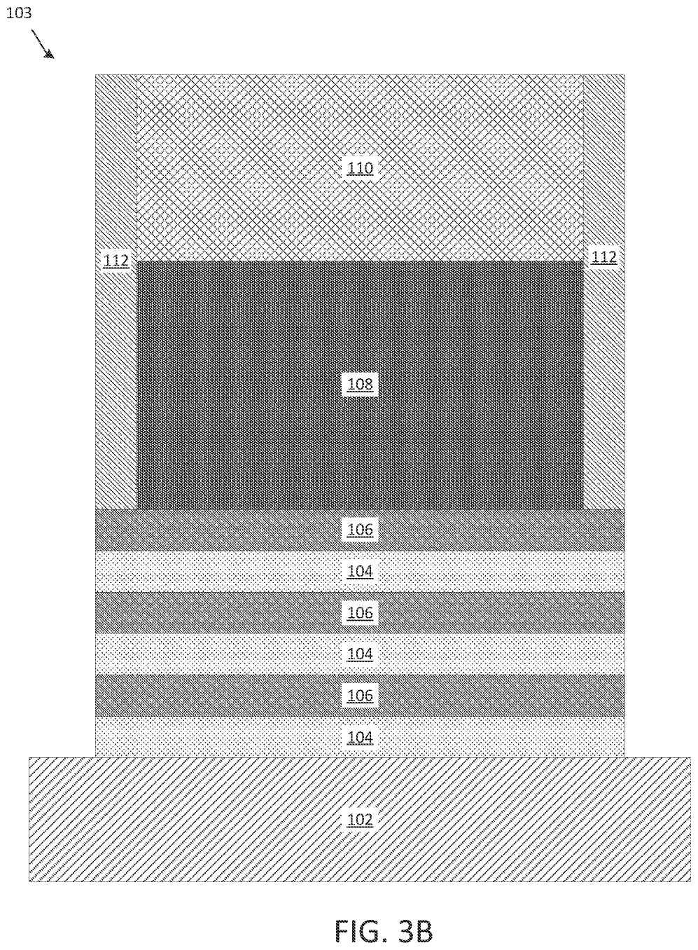

Referring now to FIG. 3A, this figure shows a schematic cross-sectional diagram for the semiconductor device including the nanosheet MOSFET device 101 of FIG. 2A at a subsequent stage of the fabrication process, taken along the MOSFET line of FIG. 1C, in accordance with embodiments. As shown in FIG. 3A, after forming the alternating layers of sacrificial layers 104 and semiconductor layers 106, nanosheet stacks are formed by any suitable patterning and material removal processes known to one of skill in the art. The semiconductor device 100 is subjected to a fin etching process to expose portions of the substrate 102. The fin etching process is achieved, for example, using a lithography patterning process (i.e., formation of the spacer layer 112) followed by a directional reactive ion etch (RIE) process, which is capable of removing portions of the sacrificial layers 104 and the active semiconductor layers 106 not covered by the dummy gate 108, the hardmask 110 and the spacer layer 112. The RIE can use a boron-based chemistry or a chlorine-based chemistry, for example, which selectively recesses the exposed portions sacrificial layers 104 and the active semiconductor layers 106 without significantly attacking the substrate 102. In certain embodiments, a dielectric isolation layer (not shown) may also be formed between the nanosheet stack and the substrate 102. FIG. 3B shows a schematic cross-sectional diagram for the semiconductor device 100 of FIG. 2B including the nanosheet MIMCAP device 103 at a subsequent stage of the fabrication process, taken along the line MIMCAP of FIG. 1C, in accordance with an embodiment. As shown in both FIGS. 3A and 3B, the sacrificial layers 104 and the semiconductor layers 106 are removed to expose the substrate 102 in the areas not covered by the dummy gate 108, the hardmask 110 and the spacer layer 112.

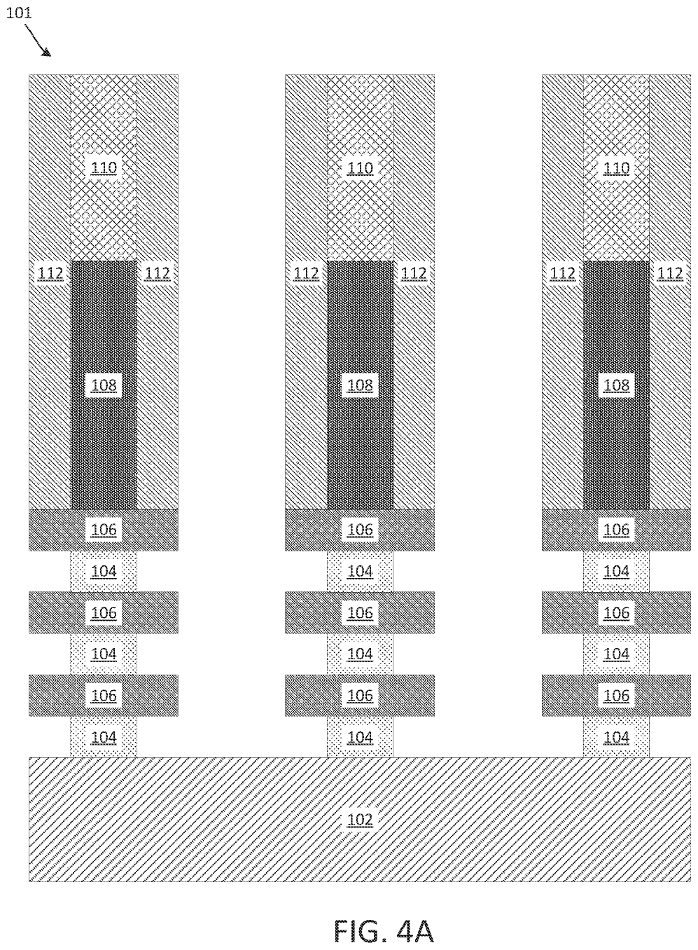

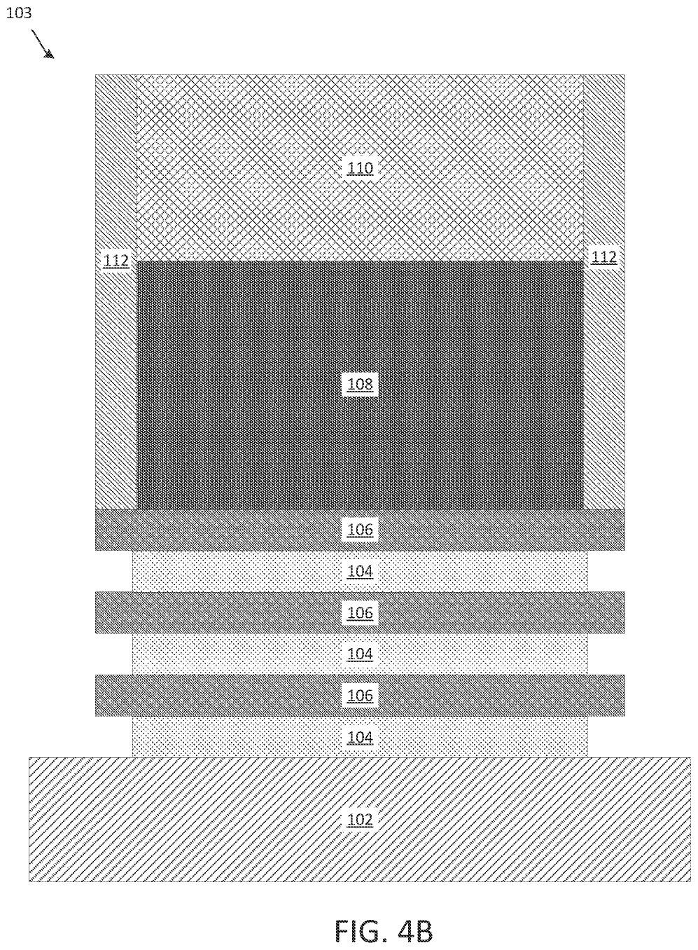

Referring now to FIG. 4A, this figure shows a schematic cross-sectional diagram for the semiconductor device 100 including the nanosheet MOSFET device 101 of FIG. 3A at a subsequent stage of the fabrication process, taken along the MOSFET line of FIG. 1C, in accordance with embodiments. As shown in FIG. 4A, portions of the sacrificial layers 104 are recessed in an inward direction so that the processed widths of the sacrificial layers 104 are less than widths of the active semiconductor layers 106. FIG. 4B shows a schematic cross-sectional diagram for the semiconductor device 100 of FIG. 3B including the nanosheet MIMCAP device 103 at a subsequent stage of the fabrication process, taken along the line MIMCAP of FIG. 1C, in accordance with an embodiment.

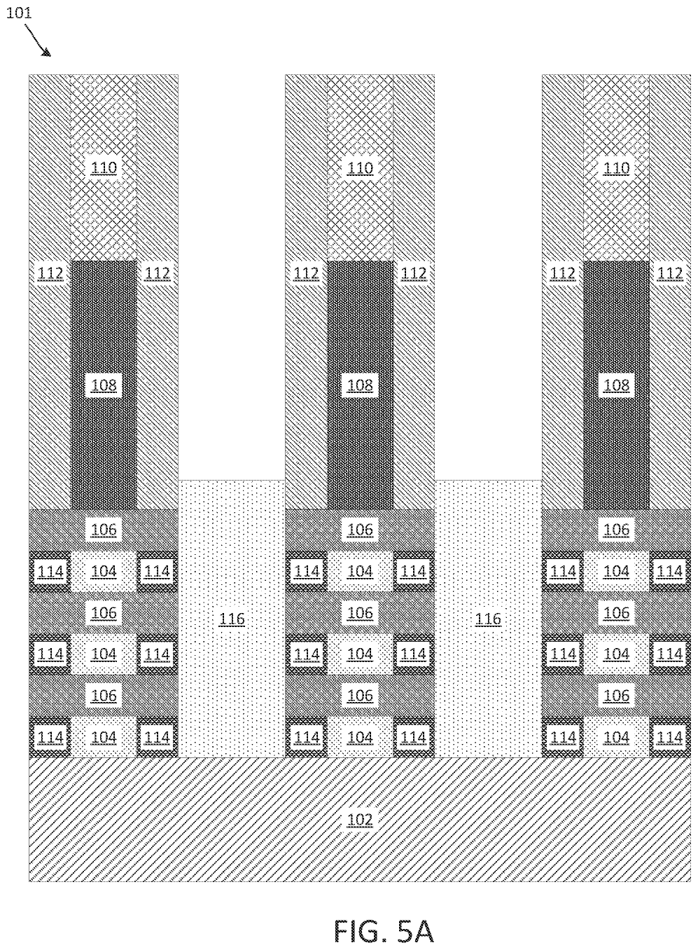

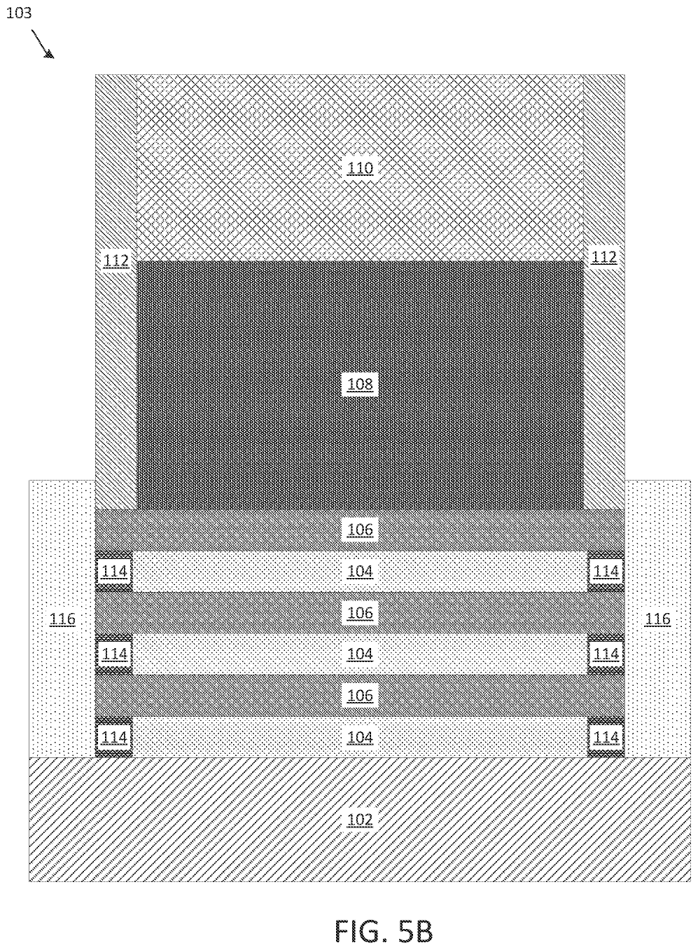

FIG. 5A shows a schematic cross-sectional diagram for the semiconductor device 100 including the nanosheet MOSFET device 101 of FIG. 4A at a subsequent stage of the fabrication process, taken along the MOSFET line of FIG. 1C, in accordance with embodiments. FIG. 5B shows a schematic cross-sectional diagram for the semiconductor device of FIG. 4B including the nanosheet MIMCAP device 103 at a subsequent stage of the fabrication process, taken along the line MIMCAP of FIG. 1C, in accordance with an embodiment. As shown in FIGS. 5A and 5B, inner spacers 114 are added in the recesses of the sacrificial layers 104. In certain embodiments, inner spacer 114 is formed by conformally depositing a dielectric material to fill the space created by SiGe indentation followed by an isotropic dielectric liner etch to create outer vertical edges to the inner spacers 114 that align with outer vertical edges of the active semiconductor layers 106. In certain embodiments, the material of the inner spacer 114 is a dielectric material such as SiN, SiO, SiBCN, SiOCN, SiCO, etc. As also shown in FIGS. 5A and 5B, source/drain (S/D) epitaxial layers 116 are formed. In FIG. 5A, the S/D epitaxial layers 116 are formed between the patterned nanosheet stacks for the MOSFET device 101. In FIG. 5B, the S/D epitaxial layers 116 are formed on the lateral sides of the MIMCAP device 103. In certain embodiments, the S/D epitaxial layers 116 are initially formed by an epitaxial growth method up to at least the level of the top of the nanosheet stack. In certain embodiments, the S/D epitaxial layers 116 are formed to a height that is higher than the upper surface of the topmost active semiconductor layer 106 of the nanosheet stack.

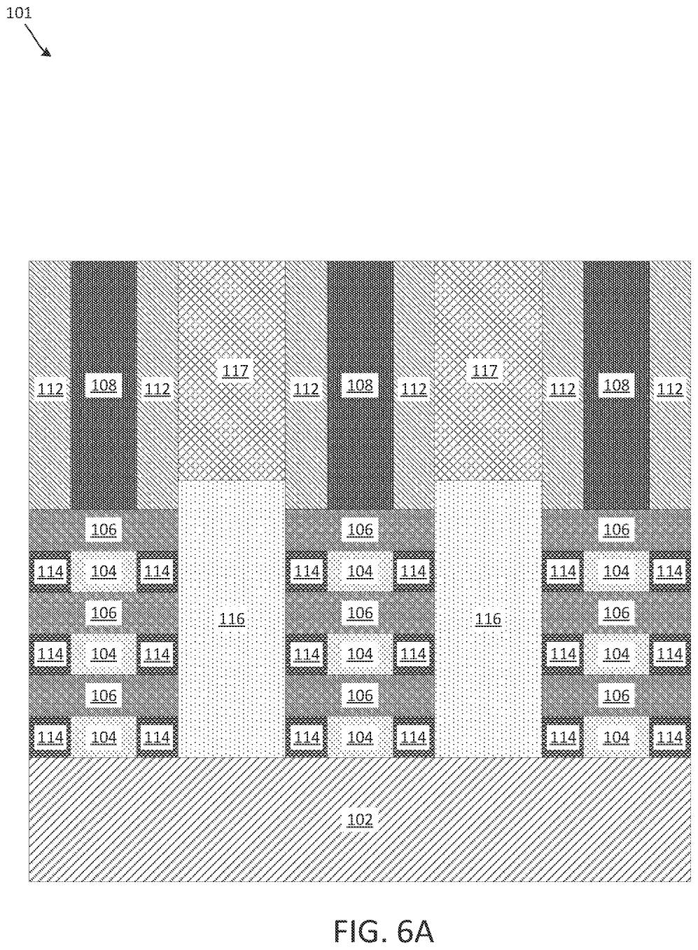

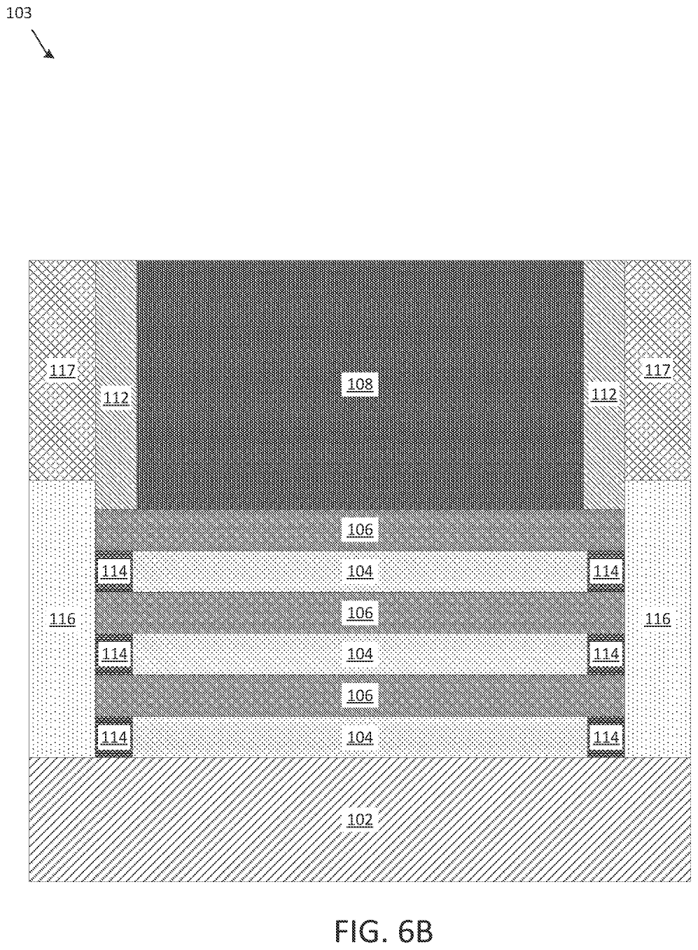

Referring now to FIG. 6A, this figure shows a schematic cross-sectional diagram for the semiconductor device 100 including the nanosheet MOSFET device 101 of FIG. 5A at a subsequent stage of the fabrication process, taken along the MOSFET line of FIG. 1C, in accordance with embodiments. FIG. 6B shows a schematic cross-sectional diagram for the semiconductor device 100 of FIG. 5B including the nanosheet MIMCAP device 103 at a subsequent stage of the fabrication process, taken along the line MIMCAP of FIG. 1C, in accordance with an embodiment. As shown in FIGS. 6A and 6B, a first interlayer dielectric (ILD) layer 117 is deposited on top of the S/D epitaxial layers 116. The first ILD layer 117 includes one or more dielectric materials such as SiN, SiO, SiBCN, SiOCN, SiCO, etc. However, it should be appreciated that any suitable dielectric material(s) may be used. In certain embodiments, a suitable material removal process, such as CMP, is performed to remove the hardmask 110 and to make the upper surfaces of the spacer layer 112, the dummy gate 108 and the first ILD layer 117 coplanar.

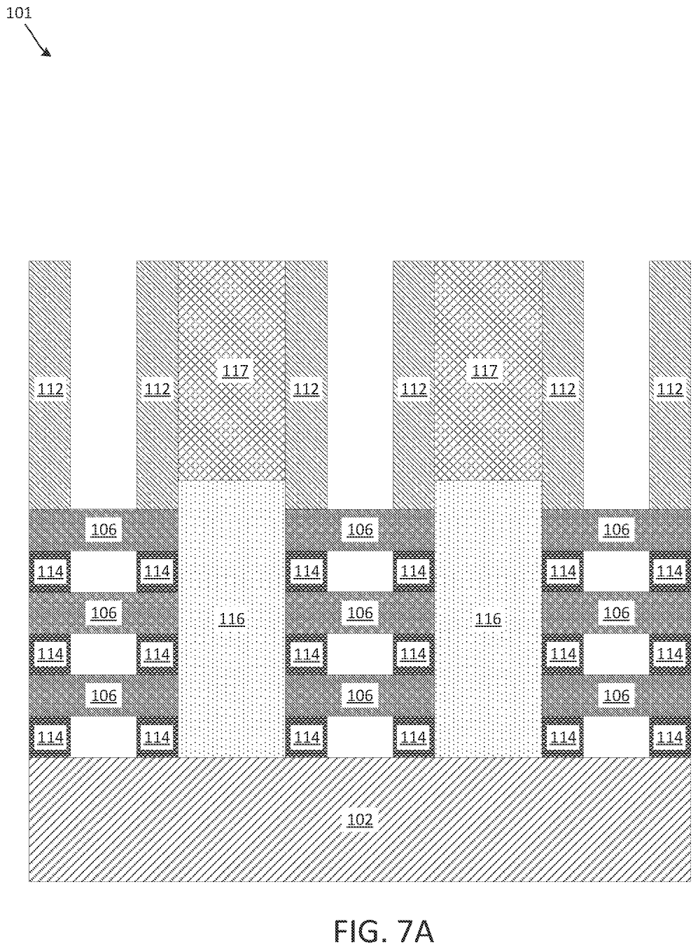

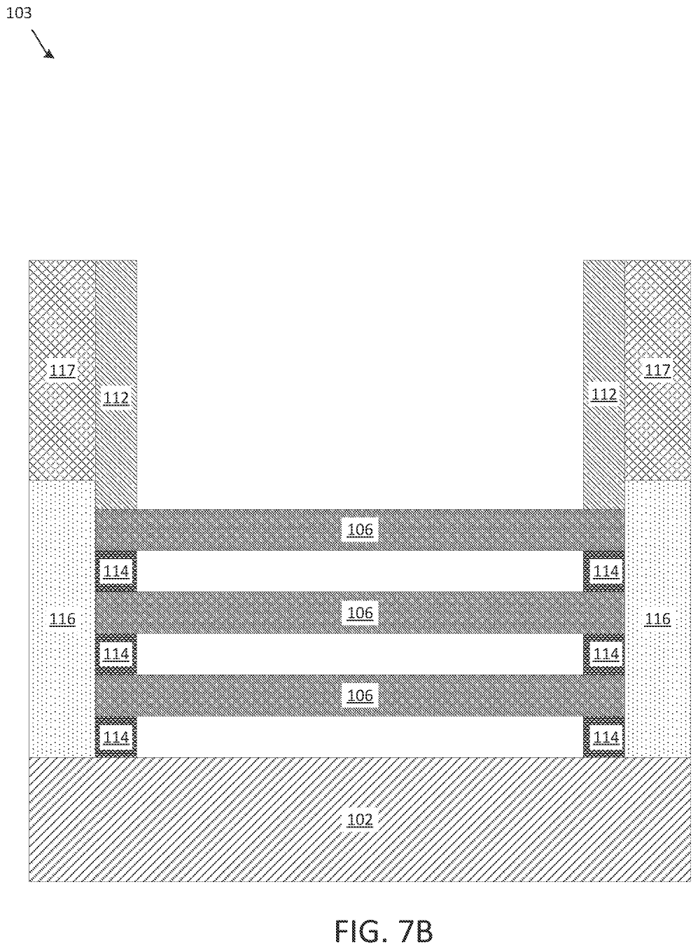

FIG. 7A shows a schematic cross-sectional diagram for the semiconductor device 100 including the nanosheet MOSFET device 101 of FIG. 6A at a subsequent stage of the fabrication process, taken along the MOSFET line of FIG. 1C, in accordance with embodiments. FIG. 7B shows a schematic cross-sectional diagram for the semiconductor device 100 of FIG. 6B including the nanosheet MIMCAP device 103 at a subsequent stage of the fabrication process, taken along the line MIMCAP of FIG. 1C, in accordance with an embodiment. As shown in FIGS. 7A and 7B, the dummy gate 108 has been removed by any suitable material removal process. Then, the sacrificial layers 104 are removed (or released). Thus, as shown in FIGS. 7A and 7B, there are void spaces between the active semiconductor layers 106 due to the removal of the sacrificial layers 104.

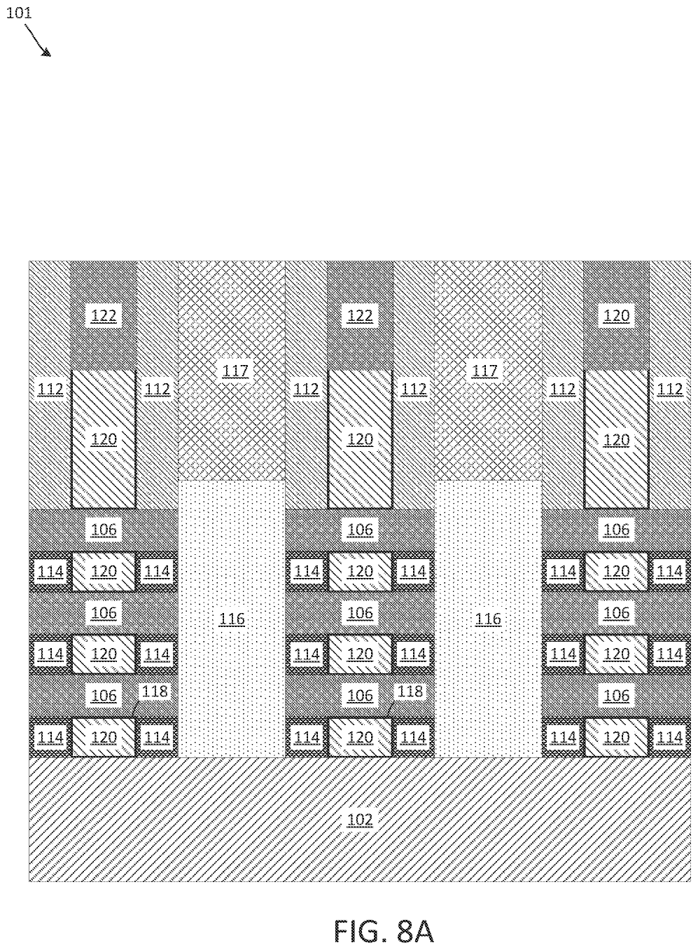

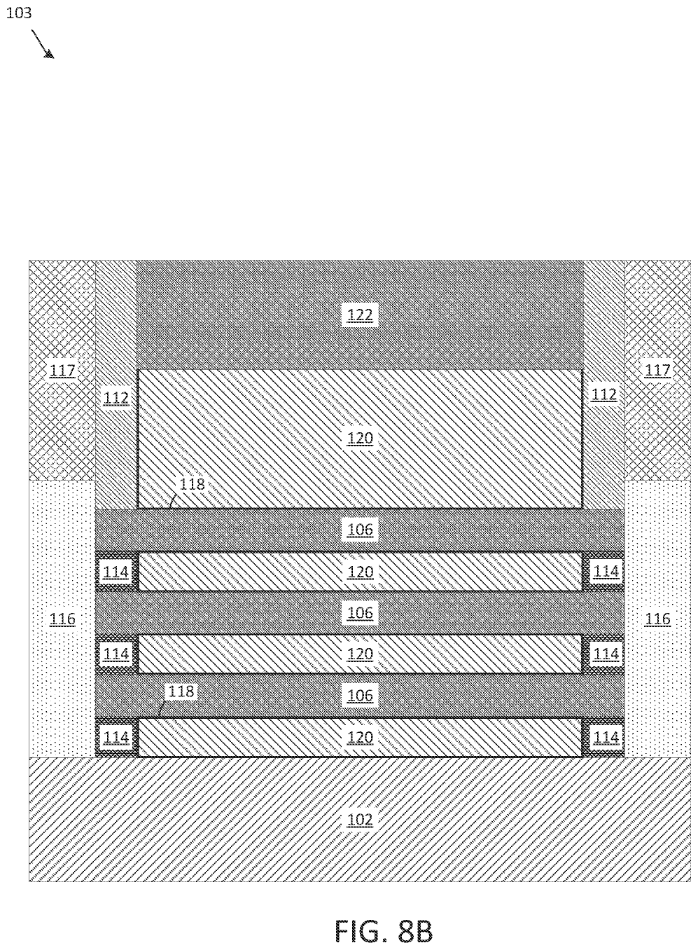

Referring now to FIG. 8A, this figure shows a schematic cross-sectional diagram for the semiconductor device 100 including the nanosheet MOSFET device 101 of FIG. 7A at a subsequent stage of the fabrication process, taken along the MOSFET line of FIG. 1C, in accordance with embodiments. Also, FIG. 8B shows a schematic cross-sectional diagram for the semiconductor device 100 of FIG. 7B including the nanosheet MIMCAP device 103 at a subsequent stage of the fabrication process, taken along the line MIMCAP of FIG. 1C, in accordance with an embodiment. As shown in FIGS. 8A and 8B, after the removal of the dummy gate 108 and sacrificial layers 104 discussed above, a high-κ layer 118 is formed to cover all of the surfaces of exposed surfaces of the spacer layers 112, the active semiconductor layers 106, the inner spacers 114. The high-κ layer 118 may comprise HfO₂, for example. Then, a metal gate (MG) layer 120 is formed to fill in the remainder of the void spaces that were created by the removal of the dummy gate 108 and the sacrificial layers 104. That is, a replacement HKMG process is then employed to deposit a gate stack (or HKMG layer 118 and metal gate layer 120) on the channel region to obtain the structure of the MOSFET device 101 as shown in FIG. 8A. Then, in certain embodiments, the HKMG layer 118 and the metal gate layer 120 are recessed below the upper surface of the first ILD layer 117, and a sacrificial (SAC) cap layer 122 is formed on the HKMG layer 118 and the metal gate layer 120. In certain embodiments, a suitable material removal process such as CMP may be used to remove any excess material and planarize the upper surfaces of the MOSFET device 101 and the MIMCAP device 103. In certain embodiments, the SAC cap layers 122 can have the same material as the spacer layer 112, or it can have different material then the spacer layer 112. Thus, the SAC cap layers 122 can be formed by recessing the HKMG layer 118 and the metal gate layer 120, depositing an electrical insulator, and planarizing the electrical insulator.

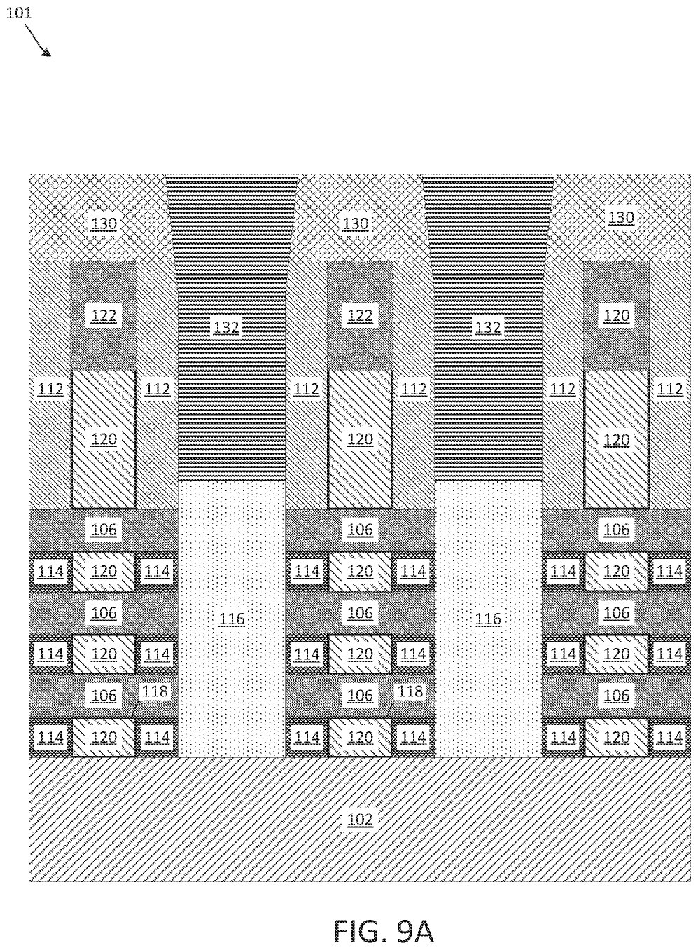

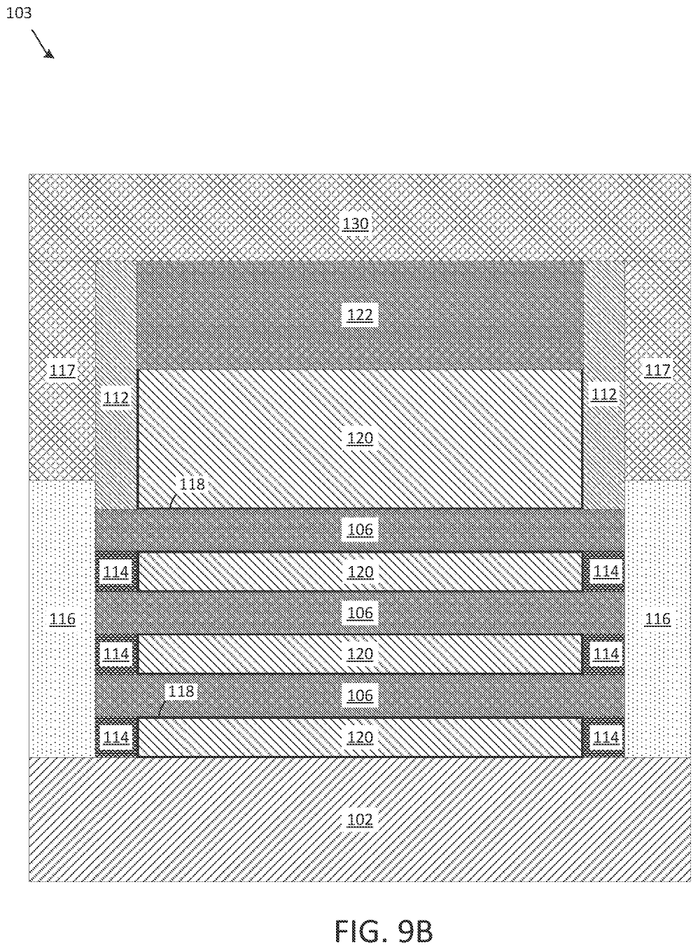

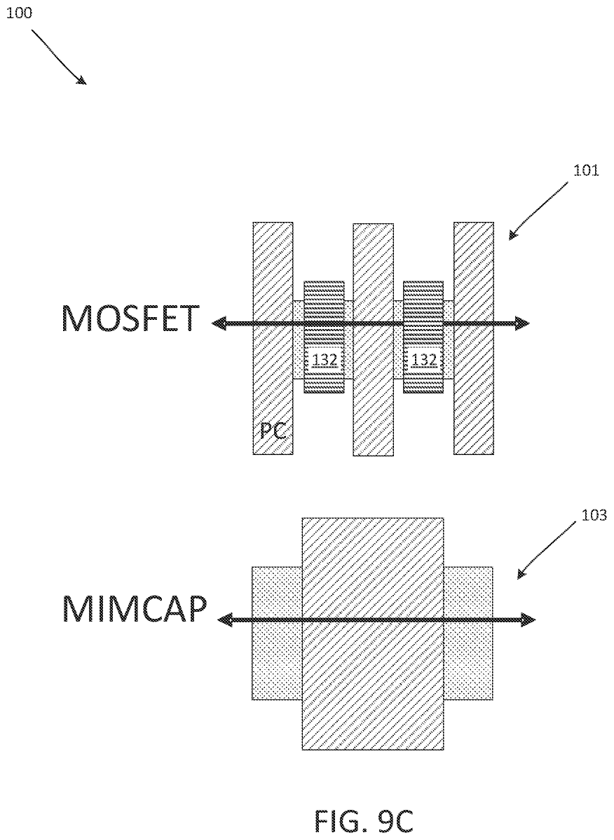

Referring now to FIG. 9A, this figure shows a schematic cross-sectional diagram for the semiconductor device 100 including the nanosheet MOSFET device 101 of FIG. 8A at a subsequent stage of the fabrication process, taken along the MOSFET line of FIG. 9C, in accordance with embodiments. FIG. 9B shows a schematic cross-sectional diagram for the semiconductor device of FIG. 8B including the nanosheet MIMCAP device 103 at a subsequent stage of the fabrication process, taken along the line MIMCAP of FIG. 9C, in accordance with an embodiment. As shown in FIGS. 9A and 9B, a second ILD layer 130 is deposited to cover the upper surfaces of the MOSFET device 101 and the MIMCAP device 103. It should be appreciated that the second ILD layer 130 may comprise the same or different materials than the first ILD layer 117. Then, as shown in FIG. 9A, MOSFET contacts 132 are formed for the MOSFET device 101 by etching away portions of the second ILD layer 130 and the first ILD layer 117 to expose the S/D epitaxial layers 116. It should be appreciated that the material of the MOSFET contacts 132 may be any suitable conductive material. FIG. 9C shows a top-down view of the semiconductor device 100 of FIGS. 9A and 9B, and shows the approximate locations in plan view of the MOSFET contacts 132 for the MOSFET device 101.

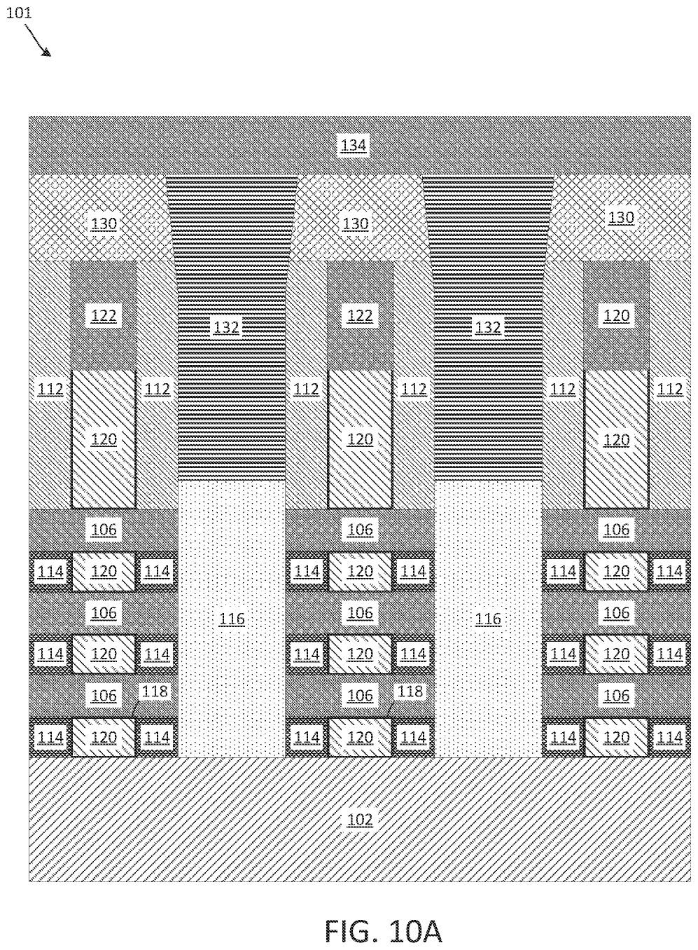

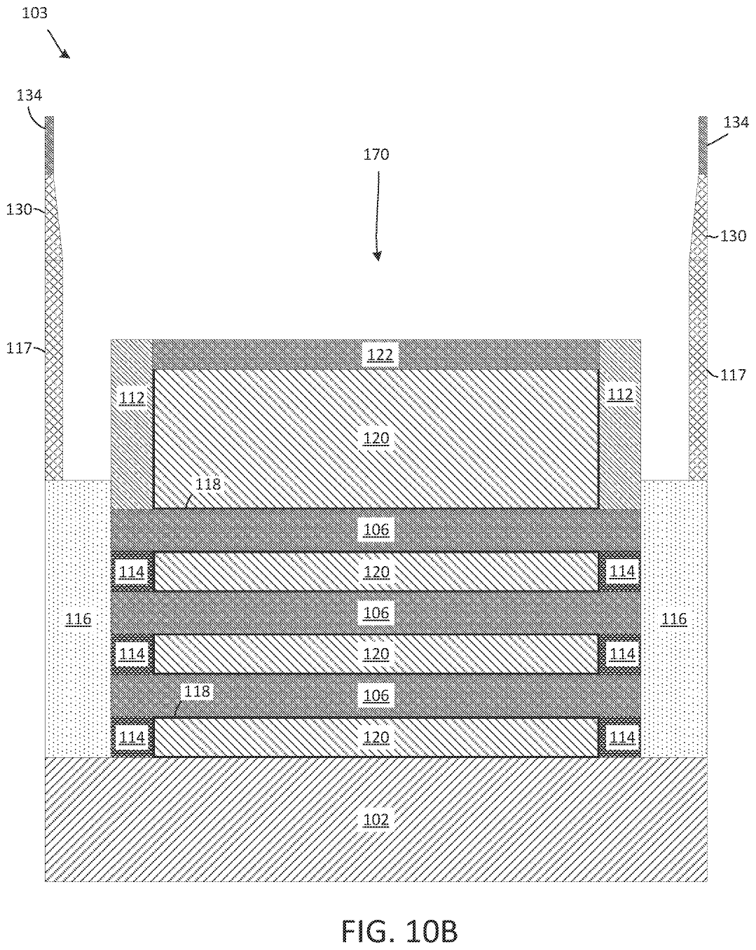

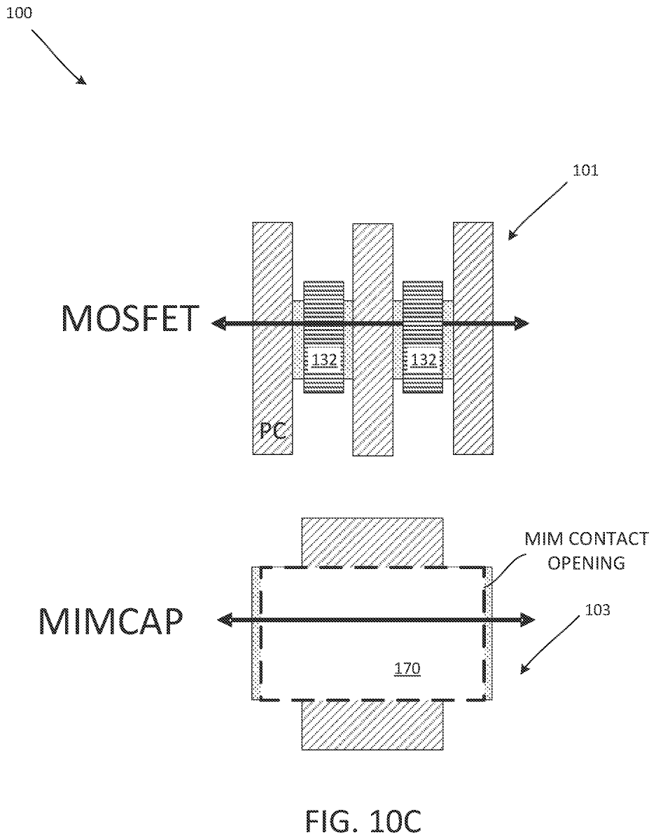

FIG. 10A shows a schematic cross-sectional diagram for the semiconductor device 100 including the nanosheet MOSFET device 101 of FIG. 9A at a subsequent stage of the fabrication process, taken along the MOSFET line of FIG. 10C, in accordance with embodiments. FIG. 10B shows a schematic cross-sectional diagram for the semiconductor device 100 of FIG. 9B including the nanosheet MIMCAP device 103 at a subsequent stage of the fabrication process, taken along the line MIMCAP of FIG. 10C, in accordance with an embodiment. As shown in FIGS. 10A and 10B, an organic planarization (OPL) layer 134 is formed over the top of the entire semiconductor device 100. Then, as shown in FIG. 10B, a MIMCAP contact opening 170 is formed for the MIMCAP device 103 by etching away portions of the OPL layer 134, the second ILD layer 130 and the first ILD layer 117. The MIMCAP contact opening 170 thus exposes surfaces of the spacer layer 112, the SAC cap layer 122, and the S/D epitaxial layer 116. FIG. 10C shows a top-down view of the semiconductor device 100 of FIGS. 10A and 10B, and also shows the approximate location of the MIMCAP contact opening 170.

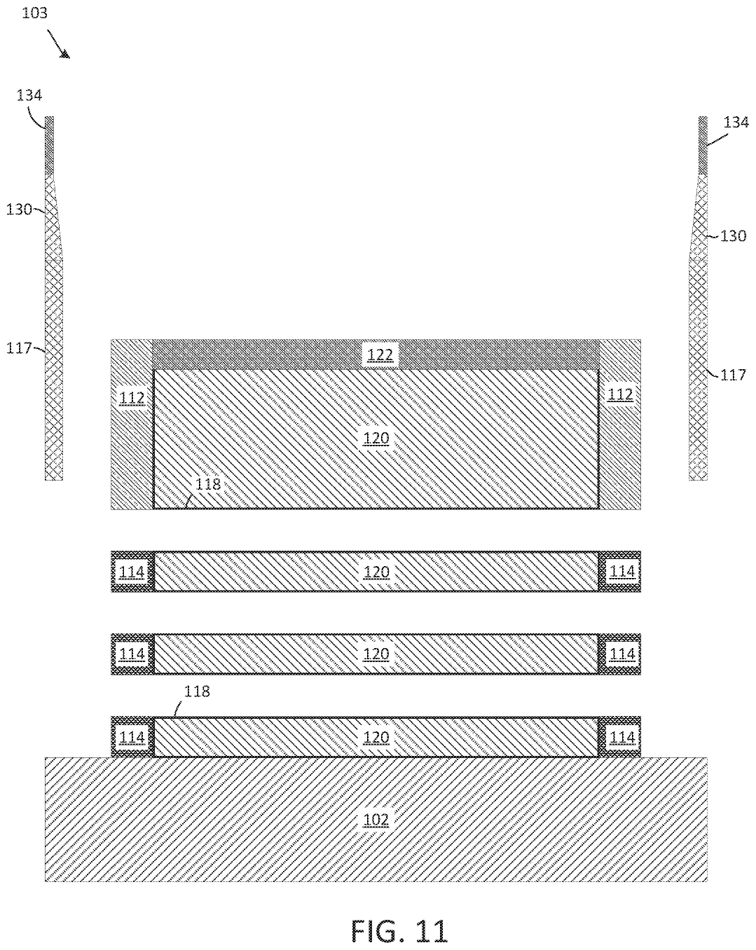

Referring now to FIG. 11, this figure shows a schematic cross-sectional diagram for the semiconductor device 100 including the nanosheet MIMCAP device of FIG. 10B at a subsequent stage of the fabrication process, taken along the MIMCAP line of FIG. 10C, in accordance with embodiments. It is noted that at this stage of the fabrication process that the cross-sectional views of the MOSFET device 101 are not included as the processing steps do not significantly affect the final structure of the MOSFET device 101. In other words, the remainder of the processing steps only affect the structure of the MIMCAP device 103. As shown in FIG. 11, the S/D epitaxial layers 116 are removed by any suitable material removal process known to one of skill in the art. Moreover, the Si channel (or the active semiconductor layers 106) are also removed by a suitable material removal process (e.g., a selective Si etching process by wet etch or dry etch, such as ammonia based wet etch). Thus, it should be appreciated that at this stage of the manufacturing process, the MIMCAP device 103 differs (in part) from the MOSFET device 101 in that the MIMCAP device 103 no longer includes the active semiconductor layers 106. In other words, because the MIMCAP device 103 structure is a metal-insulator-metal (not metal-insulator-semiconductor (or MIS)) configuration, the Si material of the active semiconductor layers 106 is removed.

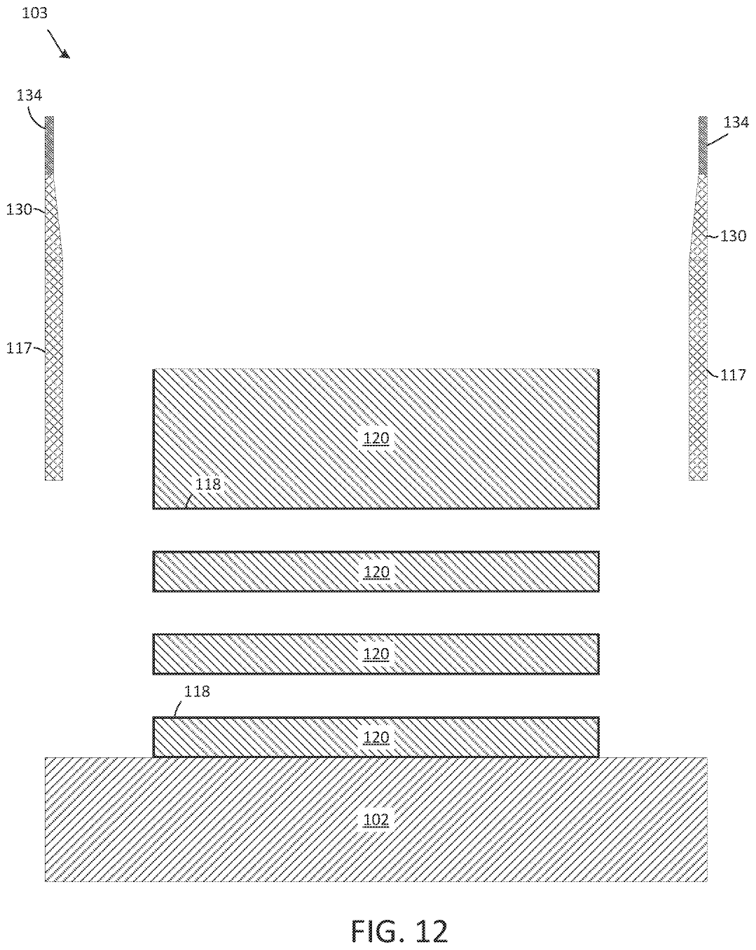

Referring now to FIG. 12, this figure shows a schematic cross-sectional diagram for the semiconductor device including the nanosheet MIMCAP device 103 of FIG. 11 at a subsequent stage of the fabrication process, taken along the MIMCAP line of FIG. 10C, in accordance with embodiments. As shown in FIG. 12, a selective material removal process (or processes) is used to remove the SAC cap layer 122, the spacer layer 112 and the inner spacers 114. It should be appreciated that one or more material removal steps and/or etchant materials may be used to remove the various materials of these layers.

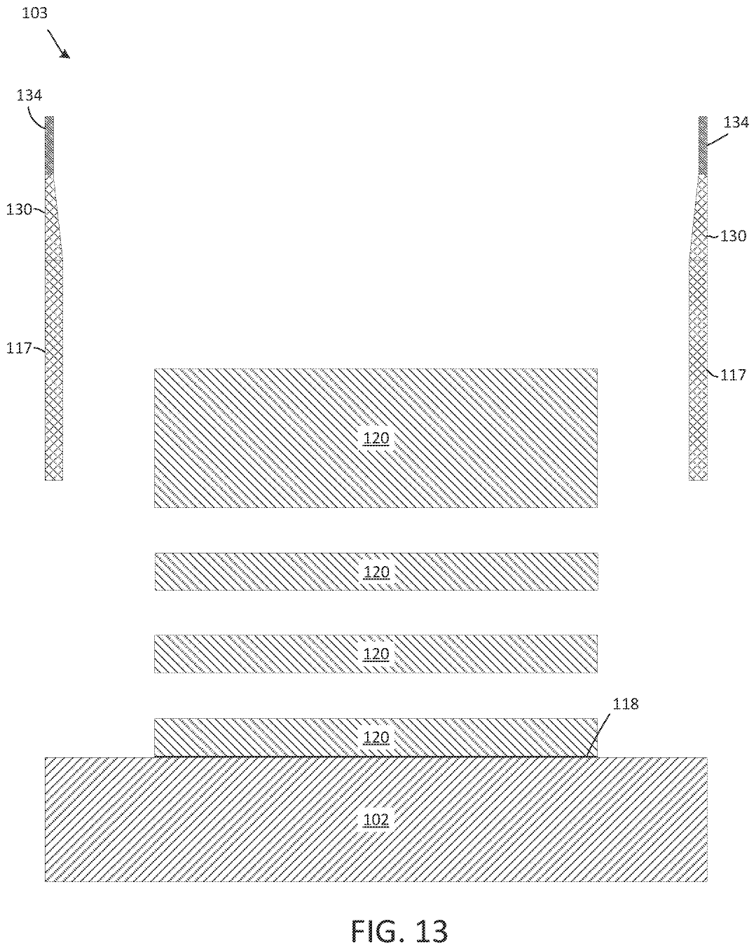

FIG. 13 shows a schematic cross-sectional diagram for the semiconductor device 100 including the nanosheet MIMCAP device 103 of FIG. 12 at a subsequent stage of the fabrication process, taken along the MIMCAP line of FIG. 10C, in accordance with embodiments. As shown in FIG. 13, a selective material removal process is used to remove the exposed portions of the high-κ layer 118. Thus, the only portion of the high-κ layer 118 that remains is that which is between the substrate 102 and the bottom nanosheet layer of the metal gate layer 120. Thus, the remaining portions of the metal gate layer 120 are exposed for further fabrication processing steps. At this stage of the manufacturing process of the MIMCAP device 103, a multilayered nanosheet metal structure (a first metal) of the metal-insulator-metal (MIM) structure remains.

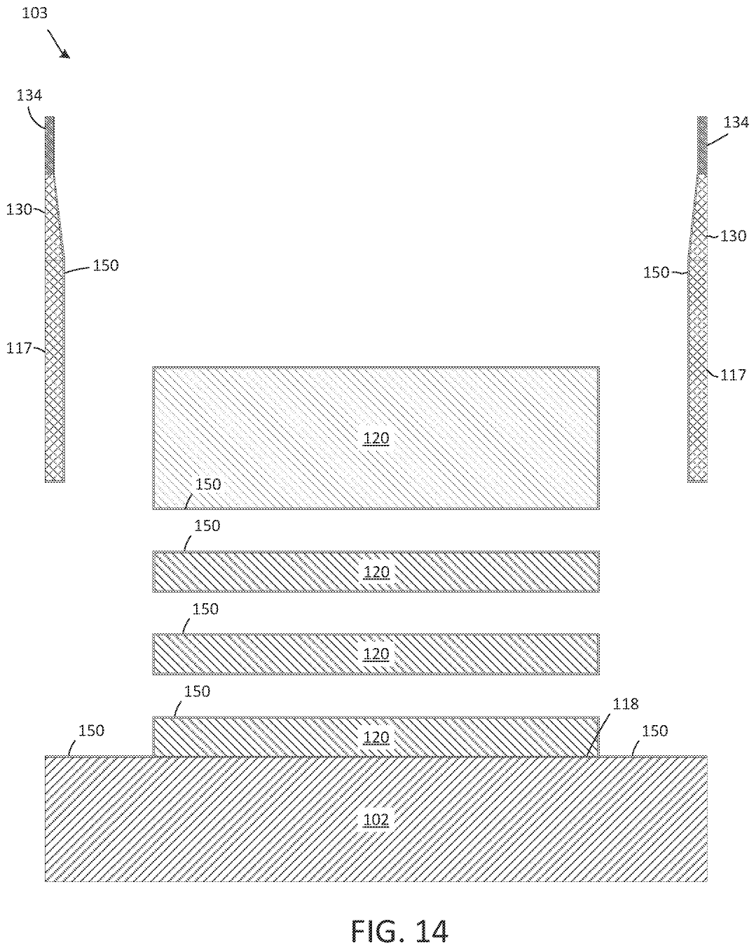

FIG. 14 shows a schematic cross-sectional diagram for the semiconductor device 100 including the nanosheet MIMCAP device 103 of FIG. 13 at a subsequent stage of the fabrication process, taken along the MIMCAP line of FIG. 10C, in accordance with embodiments. As shown in FIG. 14, a MIMCAP high-κ layer 150 is deposited on all exposed surfaces of the MIMCAP device 103. Thus, the high-κ layer has been refreshed or reformed for the MIMCAP device 103. In other embodiments, the high-κ layer 118 is not removed and replaced with the MIMCAP high-K layer 150. At this stage of the manufacturing process of the MIMCAP device 103, a multilayered nanosheet metal structure (a first metal) and the insulator of the metal-insulator-metal (MIM) structure is formed.

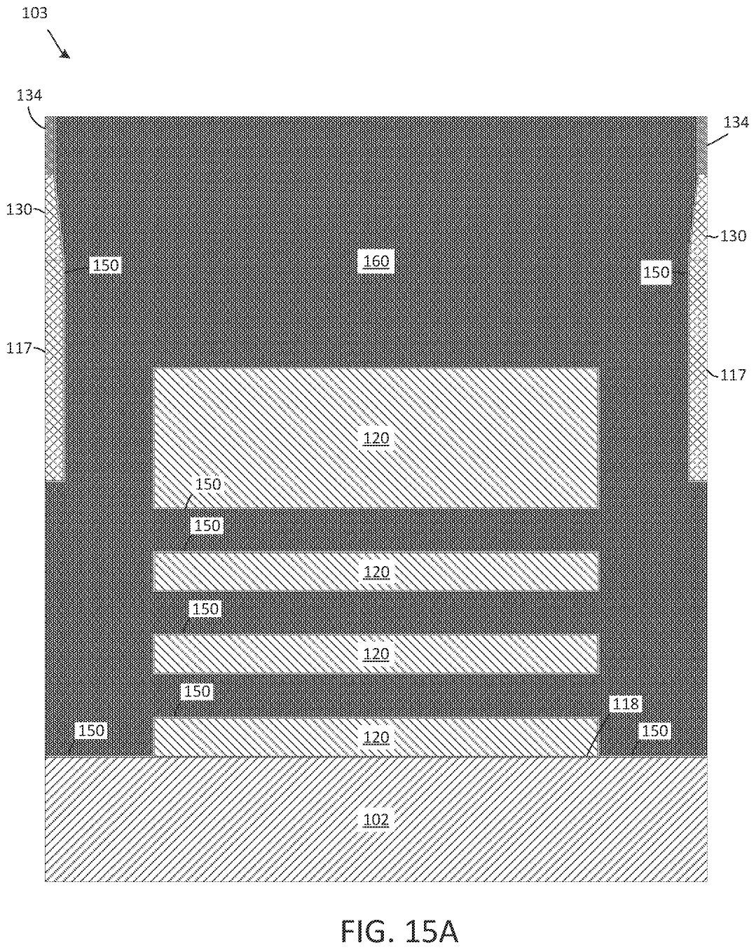

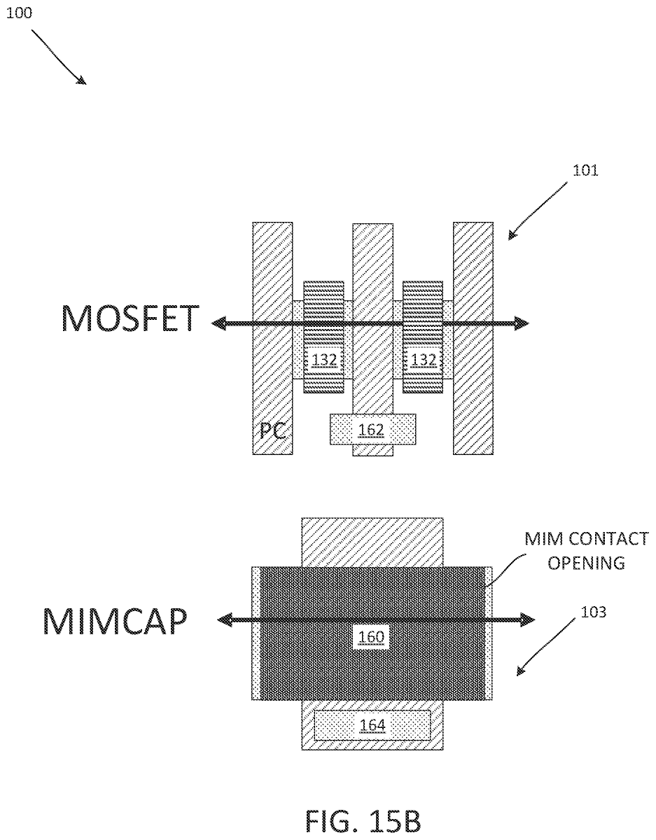

Referring now to FIG. 15A, this figure shows a schematic cross-sectional diagram for the semiconductor device 100 including the nanosheet MIMCAP device 103 of FIG. 14 at a subsequent stage of the fabrication process, taken along the MIMCAP line of FIG. 15B, in accordance with embodiments. As shown in FIG. 15A, a MIM capacitor top contact 160 is formed in the spaces in an around the nanosheet structure that includes the metal gate layer 120 and the MIMCAP high-κ layer 150. At this stage of the manufacturing process of the MIMCAP device 103, a multilayered nanosheet metal structure including the metal gate layer 120 as a first metal layer, the MIMCAP high-κ layer 150 as an insulator layer, and the MIM capacitor top contact 160 as the second metal layer of the metal-insulator-metal (MIM) structure is completed. FIG. 15B shows a top-down view of the semiconductor device 100 of FIGS. 10A and 15A, and shows the approximate location of the MIM capacitor top contact 160 (which serves as a top electrode of the MIMCAP device 103) and a gate contact 164 (which serves as a bottom electrode of the MIMCAP device 103).

Thus, in the embodiments described herein, the semiconductor device 101 includes a first type of nanosheet device (i.e., the MOSFET device 101) having a first gate insulator (i.e., the high-κ layer 118) and a first metal stack (i.e., the metal gate layer 120) wrapping around Si channels (i.e., the active semiconductor layers 106). Also, the semiconductor device 101 includes a second type of nanosheet device (i.e., the MIMCAP device 103) having one metal plate with the same first metal stack (i.e., the metal gate layer 120) as the first type of nanosheet device, a second gate insulator (i.e., the MIMCAP high-κ layer 150), and a second metal contact (i.e., the MIM capacitor top contact 160) to form the metal-insulator-metal structure of the MIMCAP. It should be noted that for the MIMCAP device 103, a remnant of the first gate insulator (i.e., the high-κ layer 118) is present at very bottom of the MIM capacitor as shown in FIG. 13, but is not present between the two metal plates. Thus, the present embodiments provide a method and structure to form high density MIM capacitors utilizing nanosheet technology.

It is to be understood that aspects of the present disclosure will be described in terms of a given illustrative architecture. However, other architectures, structures, substrate materials and process features and steps can be varied within the scope of aspects of the present embodiments.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment,” as well as other variations thereof, means that a particular feature, structure, characteristic, and so forth described in connection with the embodiment is included in at least one embodiment. Thus, the appearances of the phrase “in one embodiment” or “in an embodiment,” as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between’ two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanosheet device including
a plurality of active semiconductor layers,
a first metal stack wrapping around the active semiconductor layers, and
a first gate insulator layer between the active semiconductor layers and the first metal stack; and
a second nanosheet device including
a second metal contact,
the first metal stack wrapping around the second metal contact, and
a second gate insulator layer between the second metal contact and the first metal stack.

2. The semiconductor device of claim 1, wherein the first nanosheet device is a metal oxide semiconductor field effect transistor (MOSFET) device.

3. The semiconductor device of claim 1, wherein the second nanosheet device is a metal-insulator-metal capacitor (MIMCAP) device.

4. The semiconductor device of claim 1, further comprising a substrate,
wherein the first nanosheet device and the second nanosheet device are formed on the substrate, and
wherein a portion of the first gate insulator is formed between a bottom surface of the second nanosheet device and the substrate.

5. The semiconductor device of claim 1, wherein the first gate insulator layer includes a different material than the second gate insulator layer.

6. The semiconductor device of claim 1, wherein the first gate insulator layer comprises HfO₂.

7. The semiconductor device of claim 1, wherein the first metal stack includes a high-κ metal gate (HKMG) layer.

8. The semiconductor device of claim 1, wherein the first nanosheet device includes a source/drain (S/D) epitaxial layer in contact with the active semiconductor layers.

9. The semiconductor device of claim 1, wherein the second nanosheet device further includes a gate contact that is a bottom electrode, and wherein the second metal contact is a top electrode.

10. The semiconductor device of claim 9, wherein the first nanosheet device is a MOSFET device and the second nanosheet device is a MIMCAP device.

11. A method of forming a semiconductor device, the method comprising:
forming a nanosheet stack that includes alternating layers of sacrificial layers and active semiconductor layers;
recessing the sacrificial layers to form recessed areas of the sacrificial layers;
forming inner spacers in the recessed areas of the sacrificial layers;
removing the sacrificial layers;
forming a first gate insulator layer on the active semiconductor layers and the inner spacers;
forming a first metal stack in spaces where the sacrificial layers were removed;
removing the active silicon layers and exposed portions of the first gate insulating layer;
removing the inner spacer;
forming a second gate insulator layer on the first metal stack; and
forming a second metal contact on the second gate insulator layer such that the first metal stack wraps around the second metal contact.

12. The method of claim 11, wherein the semiconductor device is a MIMCAP device.

13. The method of claim 11, further comprising forming the semiconductor device on a substrate,
wherein a portion of the first gate insulator layer is formed between a bottom surface of the semiconductor device and the substrate.

14. The method of claim 11, further comprising:
forming a source/drain (S/D) epitaxial layer after forming the inner spacers; and
removing the S/D epitaxial layer before removing the active silicon layers.

15. The method of claim 11, wherein the first gate insulator layer includes a different material than the second gate insulator.

16. The method of claim 11, wherein the first gate insulator layer comprises HfO₂.

17. The method of claim 11, wherein the first metal stack includes a high-κ metal gate (HKMG) layer.

18. The method of claim 11, wherein the semiconductor device further includes a gate contact that is a bottom electrode, and wherein the second metal contact is a top electrode.

19. The method of claim 11, further comprising forming a MOSFET device that includes a portion of the first metal stack.

20. The method of claim 11, further comprising forming a sacrificial cap layer on the first metal stack.
